(19) United States
(12) Patent Application Publication
(10) Pub. No.: US 2018/0261737 A1
(43) Pub. Date: Sep. 13, 2018

(54) LIGHT EMITTING DEVICE

(71) Applicants: LITE-ON ELECTRONICS (GUANGZHOU) LIMITED, Guangzhou (CN); Lite-On Technology Corporation, Taipei (TW)

(72) Inventors: Bin-Yu Wu, Taipei (TW); Yao-Chi Peng, Taipei (TW)

(73) Assignees: LITE-ON ELECTRONICS (GUANGZHOU) LIMITED, GUANGZHOU (CN); Lite-On Technology Corporation, Taipei (TW)

(21) Appl. No.: 15/498,499

(22) Filed: Apr. 27, 2017

(30) Foreign Application Priority Data
Mar. 10, 2017 (CN) 201710140301.8

(51) Int. Cl. H01L 33/58; H01L 33/62; H01L 33/56; H01L 33/50; H01L 33/54

(52) U.S. Cl. CPC H01L 33/58; H01L 33/62; H01L 33/54; H01L 33/507; H01L 33/56

(57) ABSTRACT

A light emitting device includes a carrier, at least one light emitting diode (LED), a first filter layer and a first molding compound. The LED is disposed on and electrically connected to the carrier. The first filter layer is disposed above the LED and located on a light-emitting path of the LED. The first molding compound is located between the first filter layer and the LED, and doped with a fluorescent material. The LED is adapted to emit a first specific color light, and a first portion of the first specific color light is incident in the first molding compound and is reflected back into the first molding compound by the first filter layer. A second portion of the first specific color light is incident in the first molding compound and excites the fluorescent material to be converted into a second specific color light to penetrate the first filter layer.

### CROSS-REFERENCE TO RELATED APPLICATION

This application claims the priority benefit of China application no. 201710140301.8, filed on Mar. 10, 2017. The entirety of the above-mentioned patent application is hereby incorporated by reference herein and made a part of this specification.

### BACKGROUND OF THE INVENTION

### Field of the Invention

The invention relates to a light emitting device and particularly relates to a light emitting device that uses a light emitting diode (LED) as a light source.

### Description of Related Art

Generally speaking, there are two kinds of method to suppress blue light output in the light emitting device: one is to replace the existing blue LED with a light source composed of low blue light, and the other is to reduce energy of blue light in the light emitting device by using a filter. However, if the light source composed of low blue light is used to replace the existing blue LED, such replacement of the light source in the light emitting device will easily result in an increase of the production cost since the cost of a special light source is several times higher than that of a white light source. If the filter is used, the color appearance of the light emitting device will change and the total output energy will be reduced.

### SUMMARY OF THE INVENTION

The invention provides a light emitting device that has the function of suppressing a specific color light from emitting light.

The light emitting device of the invention includes a carrier, at least one LED, a first filter layer and a first molding compound. The LED is disposed on and electrically connected to the carrier. The first filter layer is disposed above the LED and located on a light-emitting path of the LED. The first molding compound is located between the first filter layer and the LED and doped with a fluorescent material. The LED is adapted to emit a first specific color light, and a first portion of the first specific color light is incident in the first molding compound and is reflected back into the first molding compound by the first filter layer. A second portion of the first specific color light is incident in the first molding compound and excites the fluorescent material to be converted into a second specific color light to penetrate the first filter layer.

In an embodiment of the invention, the first molding compound encapsulates the LED and has an arc surface structure, and the first filter layer conformally covers the first molding compound.

In an embodiment of the invention, the light emitting device further includes a second filter layer that covers the LED and the carrier. Herein, the first molding compound encapsulates the LED and the second filter layer and is located between the first filter layer and the second filter layer.

In an embodiment of the invention, the carrier has a recess and the LED is located inside the recess.

In an embodiment of the invention, the first molding compound encapsulates the LED and fills the recess. A first surface of the carrier is aligned with a second surface of the first molding compound. The first filter layer is a sheet-shaped structure and located on the second surface of the first molding compound.

In an embodiment of the invention, the light emitting device further includes a second filter layer and a second molding compound. The second filter layer is disposed between the first molding compound and the LED and located on the light-emitting path of the LED. The first filter layer, the second filter layer and the first molding compound are each a sheet-shaped structure and are each located on a first surface of the carrier. The second molding compound is disposed inside the recess of the carrier and encapsulates the LED.

In an embodiment of the invention, the second molding compound encapsulates the LED and has an arc surface structure.

In an embodiment of the invention, the recess of the carrier has an isolation region that is filled with the second molding compound or an air.

In an embodiment of the invention, when the LED emits the first specific color light, the first portion of the first specific color light is incident sequentially in the second molding compound, the second filter layer and the first molding compound and is reflected back into the first molding compound by the first filter layer. The second portion of the first specific color light is incident sequentially in the second molding compound, the second filter layer and the first molding compound and excites the fluorescent material to be converted into the second specific color light. A portion of the second specific color light penetrates the first filter layer, and another portion of the second specific color light is reflected back into the first molding compound by the second filter layer.

In an embodiment of the invention, an edge of the first filter layer, an edge of the second filter layer and an edge of the first molding compound are aligned with one another.

In an embodiment of the invention, the light emitting device further includes a second molding compound that is disposed inside the recess of the carrier and encapsulates the LED. Herein, the first filter layer and the first molding compound are each a sheet-shaped structure and are each located on a first surface of the carrier.

In an embodiment of the invention, the recess of the carrier has an isolation region that is filled with the second molding compound or an air.

In an embodiment of the invention, the light emitting device further includes a second filter layer that covers the LED. Herein, the first molding compound encapsulates the LED and the second filter layer and is located between the first filter layer and the second filter layer.

In an embodiment of the invention, the first specific color light is a blue light and the second specific color light is a yellow light.

Based on the above, according to the design of the light emitting device of the invention, the first filter layer is disposed above the LED and located on the light-emitting path of the LED. As a result, when the LED emits a first specific color light, a first portion and a second portion of the first specific color light are both incident in the first molding compound. Herein, the first portion of the first specific color light is reflected back into the first molding compound by the first filter layer, and the second portion of the first specific color light excites a fluorescent material to be converted into a second specific color light to penetrate the first filter layer. In other words, the first filter layer reflects the specific color light that does not react with the fluorescent material so as to suppress the specific color light from penetrating through the first filter layer to emit light. In this way, the light emitting device of this invention may have the function of suppressing the specific color light from emitting light. On the other hand, the first filter layer reflects the specific color light that does not react with the fluorescent material into the first molding compound so that the specific color light is made to react with the fluorescent material in the first molding compound again. As a result, loss of radiant flux may be effectively reduced and lumens (i.e. the product of the radiation measurement and the visual function) may be enhanced.

To make the aforementioned and other features and advantages of the invention more comprehensible, several embodiments accompanied with drawings are described in detail as follows.

### BRIEF DESCRIPTION OF THE DRAWINGS

The accompanying drawings are included to provide a further understanding of the invention, and are incorporated in and constitute a part of this specification. The drawings illustrate exemplary embodiments of the invention and, together with the description, serve to explain the principles of the invention.

FIG. 1 illustrates a schematic view of a light emitting device according to an embodiment of the invention.

FIG. 2 illustrates a schematic view of a light emitting device according to another embodiment of the invention.

FIG. 3 illustrates a schematic view of a light emitting device according to another embodiment of the invention.

FIG. 4 illustrates a schematic view of a light emitting device according to another embodiment of the invention.

FIG. 5 illustrates a schematic view of a light emitting device according to another embodiment of the invention.

FIG. 6 illustrates a schematic view of a light emitting device according to another embodiment of the invention.

FIG. 7 illustrates a schematic view of a light emitting device according to another embodiment of the invention.

### DESCRIPTION OF THE EMBODIMENTS

FIG. 1 illustrates a schematic view of a light emitting device according to an embodiment of the invention. With reference to FIG. 1, in this embodiment, a light emitting device 100a includes a carrier 110a, at least one light emitting diode (LED) 120 (only one LED is schematically shown in FIG. 1), a first filter layer 130a and a first molding compound 140a. The LED 120 is disposed on and electrically connected to the carrier 110a. The first filter layer 130a is disposed above the LED 120 and located on a light-emitting path of the LED 120. The first molding compound 140a is located between the first filter layer 130a and the LED 120 and is doped with a fluorescent material 142. The LED 120 is adapted to emit a first specific color light L, and a first portion L1 of the first specific color light L is incident in the first molding compound 140a and is reflected back into the first molding compound 140a by the first filter layer 130a. A second portion L2 of the first specific color light L is incident in the first molding compound 140a and excites the fluorescent material 142 to be converted into a second specific color light L′ to penetrate the first filter layer 130a.

More specifically, in this embodiment, the carrier 110a is, for example, a package carrier, the LED 120 is, for example, a blue LED, and the fluorescent material 142 is, for example, a red fluorescent material, but the invention is not limited thereto. The first molding compound 140a encapsulates the LED 120 and covers part of the carrier 110a. The first molding compound 140a has an arc surface structure 143, and the first filter layer 130a conformally covers the first molding compound 140a. Herein, the first filter layer 130a directly covers the arc surface structure 143 of the first molding compound 140a. As shown in FIG. 1, in this embodiment, the first molding compound 140a is essentially a lenticular structure in appearance so as to further enhance the light emitting effect of the light emitting device 100a.

With reference to FIG. 1 again, when the LED 120 emits the first specific color light L (such as a blue light), the first portion L1 and the second portion L2 of the first specific color light L are both incident in the first molding compound 140a. Herein, the first portion L1 of the first specific color light L is reflected back into the first molding compound 140a by the first filter layer 130a, and the second portion L2 of the first specific color light L excites the fluorescent material 142 (such as a red florescent material) to be converted into the second specific color light L′ (such as a yellow light) to penetrate the first filter layer 130a. In other words, the first filter layer 130a reflects the first specific color light L (such as a blue light) that does not react with the fluorescent material 142 so as to suppress the first specific color light L (such as a blue light) from penetrating through the first filter layer 130a to emit light. In this way, the light emitting device 100a of this embodiment may have the function of suppressing the first specific color light L (such as a blue light) from emitting light. On the other hand, the first filter layer 130a reflects the first specific color light L (such as a blue light) that does not react with the fluorescent material 142 into the first molding compound 140a so that the first specific color light L is made to react with the fluorescent material 142 in the first molding compound 140a again. As a result, loss of radiant flux may be effectively reduced and lumens may be enhanced.

It should be noted here that the reference numerals and part of the contents of the foregoing embodiment are used in the following embodiments, in which identical reference numerals indicate identical or similar components, and repeated description of the same technical contents is omitted. Please refer to the description of the foregoing embodiment for the omitted contents, which will not be repeated hereinafter.

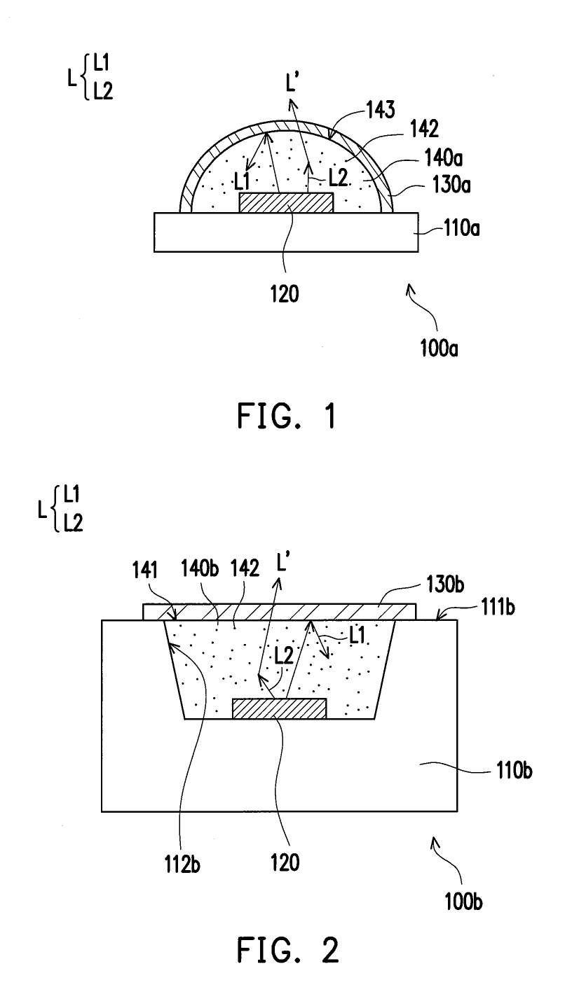

FIG. 2 illustrates a schematic view of a light emitting device according to another embodiment of the invention. With reference to FIG. 2 and FIG. 1 simultaneously, a light emitting device 100b of this embodiment is similar to the light emitting device 100a of FIG. 1. The differences between the two are that in this embodiment, a carrier 110b has a recess 112b, a LED 120 is located inside the recess 112b, and a first molding compound 140b encapsulates the LED 120 and preferably fills the recess 112b. Of course, in other unillustrated embodiments, the first molding compound 140b may also not fill the entire recess 112b, such as only filling to 80 percent full. Specifically, a first surface 111b of the carrier 110b is aligned with a second surface 141 of the first molding compound 140b. A first filter layer 130b is embodied to be a sheet-shaped structure and located on the second surface 141 of the first molding compound 140b. Herein, the first filter layer 130b essentially covers the second surface 141 of the first molding compound 140b and part of the first surface 111b of the carrier 110b. But in other unillustrated embodiments, as long as the first filter layer 130b is located on a light-emitting path of the LED 120, the embodiments all fall within the range to be protected by the invention.

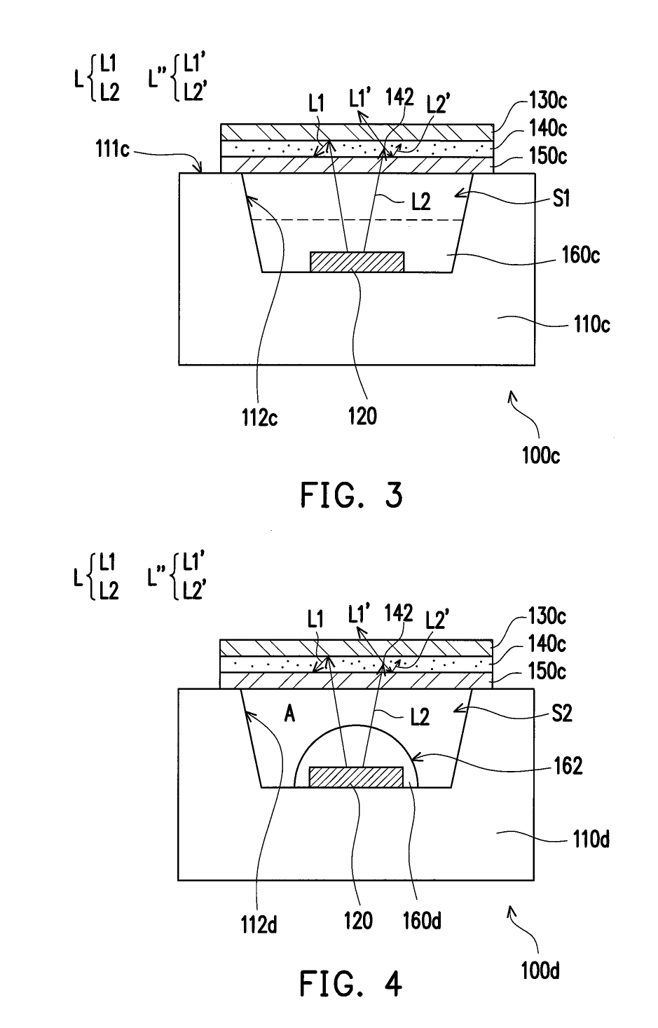

FIG. 3 illustrates a schematic view of a light emitting device according to another embodiment of the invention. With reference to FIG. 3 and FIG. 2 simultaneously, a light emitting device 100c of this embodiment is similar to the light emitting device 100b of FIG. 2. The difference between the two is that a first molding compound 140c of this embodiment is dissimilar to the first molding compound 140b of FIG. 2 in terms of structural form. Specifically, in this embodiment, the light emitting device 100c further includes a second filter layer 150c and a second molding compound 160c. The second filter layer 150c is disposed between the first molding compound 140c and a LED 120 and located on a light-emitting path of the LED 120. A first filter layer 130c, the second filter layer 150c and the first molding compound 140c are each a sheet-shaped structure and are each located on a first surface 111c of a carrier 110c. Herein, an edge of the first filter layer 130c, an edge of the second filter layer 150c and an edge of the first molding compound 140c are essentially aligned with one another, but the invention is not limited thereto. In particular, in this embodiment, the first filter layer 130c and the second filter layer 150c may suppress specific color lights of different colors respectively from penetrating through.

Furthermore, in this embodiment, the second molding compound 160c is disposed inside a recess 112c of the carrier 110c and encapsulates the LED 120. In this embodiment, the recess 112c of the carrier 110c is embodied to have an isolation region S1. Herein, the isolation region S1 is located between the second filter layer 150c and the LED 120 and is filled with the second molding compound 160c. In other words, in this embodiment, the second molding compound 160c, in addition to completely encapsulating the LED 120, also fills the entire recess 112c. Herein, the difference between the second molding compound 160c and the first molding compound 140c is that the second molding compound 160c is not doped with a fluorescent material and is only an encapsulating material layer, the material of which is, for example, silica gel or epoxy resin, but the invention is not limited thereto.

With reference to FIG. 3 again, when the LED 120 emits a first specific color light L (such as a blue light), a first portion L1 of the first specific color light L is incident sequentially in the second molding compound 160c, the second filter layer 150c and the first molding compound 140c and is reflected back into the first molding compound 140c by the first filter layer 130c. A second portion L2 of the first specific color light L is incident sequentially in the second molding compound 160c, the second filter layer 150c and the first molding compound 140c and excites a fluorescent material 142 (such as a red fluorescent material) to be converted into a second specific color light L″ (such as a yellow light). A portion L1′ of the second specific color light L″ penetrates the first filter layer 130c, and another portion L2′ of the second specific color light L″ is reflected back into the first molding compound 140c by the second filter layer 150c. In other words, the first filter layer 130c may suppress the first specific color light L (such as a blue light) from penetrating through to emit light, and the second filter layer 150c may suppress the second specific color light L″ from penetrating through to avoid a reentry into the recess 112c of the carrier 110c. In short, the light emitting device 100c of this embodiment may have the function of suppressing the specific color light (such as a blue light) from emitting light.

On the other hand, in this embodiment, the first filter layer 130c reflects the first specific color light L that does not react with the fluorescent material 142 into the first molding compound 140c so that the first specific color light L is made to react with the fluorescent material 142 in the first molding compound 140c again. And the second filter layer 150c reflects the second specific color light L″ that attempts to be incident back in the second molding compound 160c into the first molding compound 140c so that the second specific color light L″ is made to react with the fluorescent material 142 in the first molding compound 140c again. In this way, the light emitting device 100c of this embodiment may effectively reduce loss of radiant flux and enhance lumens.

FIG. 4 illustrates a schematic view of a light emitting device according to another embodiment of the invention. With reference to FIG. 4 and FIG. 3 simultaneously, a light emitting device 100d of this embodiment is similar to the light emitting device 100c of FIG. 3. The difference between the two is that in this embodiment, a second molding compound 160d encapsulates a LED 120 and has an arc surface structure 162. As shown in FIG. 4, in this embodiment, the second molding compound 160d is essentially a lenticular structure in appearance so as to further enhance the light emitting effect of the light emitting device 100d. In addition, in this embodiment, an isolation region S2 of a recess 112d of a carrier 110d is essentially filled with an air A. In other words, in this embodiment, the second molding compound 160d essentially encapsulates the LED 120 but does not fill the entire recess 112d.

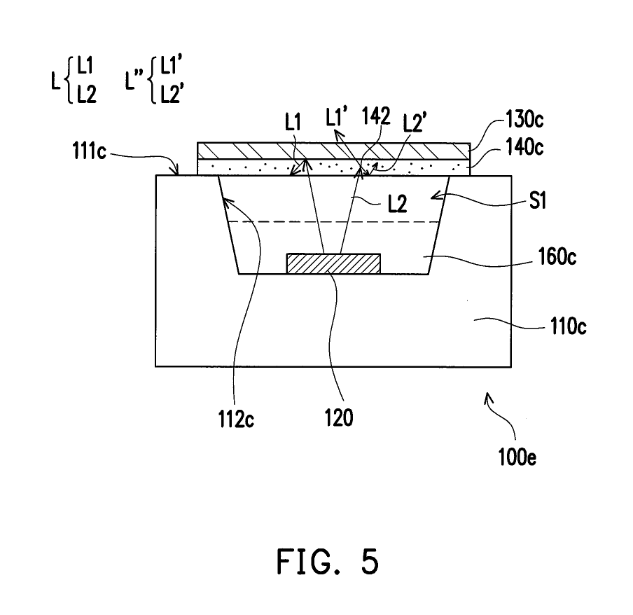

FIG. 5 illustrates a schematic view of a light emitting device according to another embodiment of the invention. With reference to FIG. 5 and FIG. 3 simultaneously, a light emitting device 100e of this embodiment is similar to the light emitting device 100c of FIG. 3. The difference between the two is that in this embodiment, the light emitting device 100e does not have the second filter layer 150c of FIG. 3. In other words, in this embodiment, a first molding compound 140c and a first filter layer 130c are each a sheet-shaped structure and are each located on a first surface 111c of a carrier 110c. When a LED 120 emits a first specific color light L (such as a blue light), a first portion L1 of the first specific color light L is incident sequentially in a second molding compound 160c and the first molding compound 140c and is reflected back into the first molding compound 140c by the first filter layer 130c. A second portion L2 of the first specific color light L is incident sequentially in the second molding compound 160c and the first molding compound 140c and excites a fluorescent material 142 (such as a red fluorescent material) to be converted into a second specific color light L″ (such as a yellow light). A portion L1′ of the second specific color light L″ penetrates the first filter layer 130c, and another portion L2′ of the second specific color light L″ may be reflected back into the first molding compound 140c via a recess 112c of the carrier 110c. In other words, the first filter layer 130c may suppress the first specific color light L (such as a blue light) from penetrating through to emit light. Therefore, the light emitting device 100e of this embodiment may have the function of suppressing the specific color light (such as a blue light) from emitting light.

It is worth noting that although the second molding compound 160c is shown in FIG. 5 in the form of filling the recess 112c, but in other unillustrated embodiments, the second molding compound 160c may also not fill the entire recess 112c, such as only filling to 80 percent full, and such embodiments still fall within the range to be protected by the invention. Of course, in other unillustrated embodiments, it may not be necessary to provide a second molding compound, and such embodiments still fall within the range to be protected by the invention.

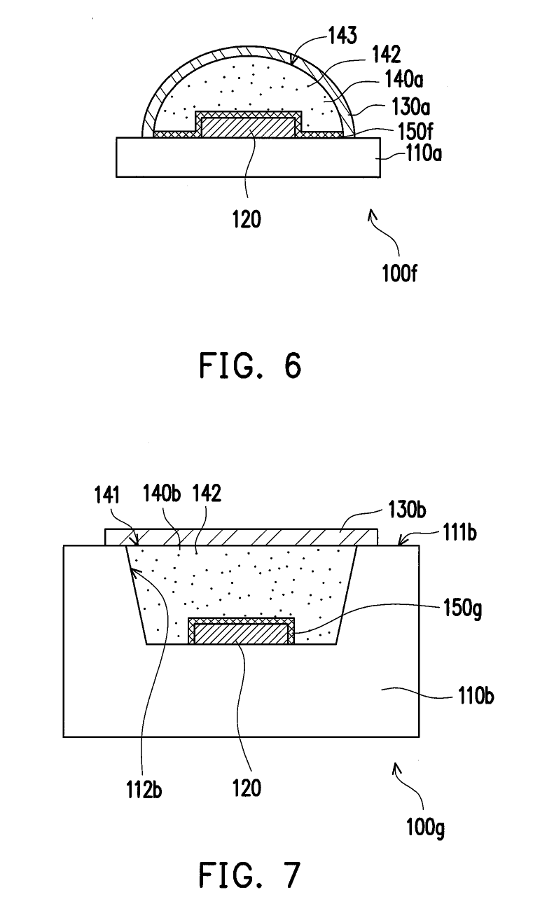

FIG. 6 illustrates a schematic view of a light emitting device according to another embodiment of the invention. With reference to FIG. 6 and FIG. 1 simultaneously, a light emitting device 100f of this embodiment is similar to the light emitting device 100a of FIG. 1. The difference between the two is that the light emitting device 100f of this embodiment further includes a second filter layer 150f that covers a LED 120 and a carrier 110a. Herein, a first molding compound 140a encapsulates the LED 120 and the second filter layer 150f and is located between a first filter layer 130a and the second filter layer 150f. Because the first filter layer 130a and the second filter layer 150f of this embodiment may suppress specific color lights of different colors respectively from penetrating through, the light emitting device 100f of this embodiment may have the function of suppressing a specific color light (such as a blue light) from emitting light.

FIG. 7 illustrates a schematic view of a light emitting device according to another embodiment of the invention. With reference to FIG. 7 and FIG. 2 simultaneously, a light emitting device 100g of this embodiment is similar to the light emitting device 100b of FIG. 2. The difference between the two is that the light emitting device 100g of this embodiment further includes a second filter layer 150g that covers a LED 120. Herein, a first molding compound 140b encapsulates the LED 120 and the second filter layer 150g and is located between a first filter layer 130b and the second filter layer 150g. Because the first filter layer 130b and the second filter layer 150g of this embodiment may suppress specific color lights of different colors respectively from penetrating through, the light emitting device 100g of this embodiment may have the function of suppressing a specific color light (such as a blue light) from emitting light.

In summary of the above, according to the design of the light emitting device of the invention, the first filter layer is disposed above the LED and located on the light-emitting path of the LED. As a result, when the LED emits a first specific color light, a first portion and a second portion of the first specific color light are both incident in the first molding compound. Herein, the first portion of the first specific color light is reflected back into the first molding compound by the first filter layer, and the second portion of the first specific color light excites a fluorescent material to be converted into a second specific color light to penetrate the first filter layer. In other words, the first filter layer reflects the specific color light that does not react with the fluorescent material so as to suppress the specific color light from penetrating through the first filter layer to emit light. In this way, the light emitting device of this invention may have the function of suppressing the specific color light from emitting light. On the other hand, the first filter layer reflects the specific color light that does not react with the fluorescent material into the first molding compound so that the specific color light is made to react with the fluorescent material in the first molding compound again. As a result, loss of radiant flux may be effectively reduced and lumens may be enhanced.

Although the embodiments are already disclosed as above, these embodiments should not be construed as limitations on the scope of the invention. It will be apparent to those ordinarily skilled in the art that various modifications and variations can be made to the disclosed embodiments without departing from the scope or spirit of this invention. In view of the foregoing, it is intended that the invention covers modifications and variations provided that they fall within the scope of the following claims and their equivalents.

1. A light emitting device, comprising:
a carrier;
at least one light emitting diode (LED), disposed on and electrically connected to the carrier;
a first filter layer, disposed above the at least one LED and located on a light-emitting path of the at least one LED; and
a first molding compound, located between the first filter layer and the at least one LED and doped with a fluorescent material, wherein the first molding compound encapsulates the at least one LED and has an arc surface structure, and the first filter layer conformally covers the first molding compound, the at least one LED is adapted to emit a first specific color light, a first portion of the first specific color light is incident in the first molding compound and is reflected back into the first molding compound by the first filter layer, and a second portion of the first specific color light is incident in the first molding compound and excites the fluorescent material to be converted into a second specific color light to penetrate the first filter layer.

2. (canceled)

3. The light emitting device as recited in claim 1, further comprising:
a second filter layer, covering the at least one LED and the carrier, wherein the first molding compound encapsulates the at least one LED and the second filter layer and is located between the first filter layer and the second filter layer.

4-13. (canceled)

14. The light emitting device as recited in claim 1, wherein the first specific color light is a blue light and the second specific color light is a yellow light.

15. The light emitting device as recited in claim 1, wherein the carrier is a package carrier.

16. The light emitting device as recited in claim 1, wherein the at least one light emitting diode is a blue LED.

17. The light emitting device as recited in claim 1, wherein the fluorescent material is a red fluorescent material.

18. The light emitting device as recited in claim 1, wherein the first filter layer directly covers the arc surface structure of the first molding compound.
